(19) United States
(12) Patent Application Publication
(10) Pub. No.: US 2024/0274756 A1
(43) Pub. Date: Aug. 15, 2024

(54) LIGHT-EMITTING DEVICES AND METHODS FOR MANUFACTURING THE SAME, DISPLAY PANELS AND DISPLAY APPARATUSES

(71) Applicants: BEIJING BOE TECHNOLOGY DEVELOPMENT CO., LTD., Beijing (CN); BOE TECHNOLOGY GROUP CO., LTD., Beijing (CN)

(72) Inventor: Dong LI, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/042,944

(22) PCT Filed: Feb. 23, 2022
(86) PCT No.: PCT/CN2022/077493

§ 371 Date: Feb. 24, 2023

(51) Int. Cl. H01L 33/50; H01L 25/075; H01L 33/00; H01L 33/04

(52) U.S. Cl. CPC H01L 33/502; H01L 25/0753; H01L 33/005; H01L 33/04

(57) ABSTRACT

A light-emitting device includes a first electrode, an electron transporting layer disposed on a side of the first electrode, a quantum dot light-emitting layer disposed on a side of the electron transporting layer away from the first electrode, a second electrode disposed on a side of the quantum dot light-emitting layer away from the first electrode, and a plurality of adjustment patterns disposed between the first electrode and the quantum dot light-emitting layer. Orthographic projections of the plurality of adjustment patterns on a reference plane are distributed at intervals. The plurality of adjustment patterns are each in contact with the electron transporting layer. At least a portion of an orthographic projection of the electron transporting layer on the reference plane is located in a gap between the orthographic projections of the plurality of adjustment patterns on the reference plane.

### CROSS-REFERENCE TO RELATED APPLICATION

This application is a national phase entry under 35 USC 371 of International Patent Application No. PCT/CN2022/077493, filed on Feb. 23, 2022, which is incorporated herein by reference in its entirety.

### TECHNICAL FIELD

The present disclosure relates to the field of display technologies, and in particular, to light-emitting devices and methods for manufacturing the same, display panels and display apparatuses.

### BACKGROUND

As a new type of luminescent material, quantum dots have high light-color purity, high light-emitting quantum efficiency, adjustable light-emitting color, long service life and other advantages, and thus have become a research hotspot of new light-emitting diode (LED) luminescent materials at present. Therefore, quantum dot light-emitting diodes (QLED) using quantum dot materials as light-emitting layers have become a main direction of research for new display apparatuses.

### SUMMARY

In an aspect, a light-emitting device is provided. The light-emitting device includes a first electrode, an electron transporting layer, a quantum dot light-emitting layer, and a second electrode. The electron transporting layer is disposed on a side of the first electrode. The quantum dot light-emitting layer is disposed on a side of the electron transporting layer away from the first electrode. The second electrode is disposed on a side of the quantum dot light-emitting layer away from the first electrode. The light-emitting device further includes a plurality of adjustment patterns. Orthographic projections of the plurality of adjustment patterns on a reference plane are distributed at intervals. The reference plane is parallel to a plane in which the first electrode is located. The plurality of adjustment patterns are disposed between the first electrode and the quantum dot light-emitting layer, and are each in contact with the electron transporting layer. At least a portion of an orthographic projection of the electron transporting layer on the reference plane is located in a gap between the orthographic projections of the plurality of adjustment patterns on the reference plane. The plurality of adjustment patterns are configured to achieve one of blocking electrons transmitted from the first electrode to the quantum dot light-emitting layer and inducing electron traps to trap the electrons transmitted from the first electrode to the quantum dot light-emitting layer.

In some embodiments, the plurality of adjustment patterns include an insulating transparent oxide material.

In some embodiments, the plurality of adjustment patterns include a hole-transporting-type transparent oxide material.

In some embodiments, a lowest unoccupied molecular orbital level of the hole-transporting-type transparent oxide material is shallower than a lowest unoccupied molecular orbital level of the electron transporting layer.

In some embodiments, the light-emitting device further includes a hole transporting layer disposed between the quantum dot light-emitting layer and the second electrode, and a material of the plurality of adjustment patterns is the same as a material of the hole transporting layer.

In some embodiments, the plurality of adjustment patterns include at least two two-dimensional semiconductor layers, and the at least two two-dimensional semiconductor layers form a moiré superlattice structure.

In some embodiments, the plurality of adjustment patterns are arranged in a plurality of rows and a plurality of columns. Any two adjacent rows of adjustment patterns have an equal distance therebetween, and/or any two adjacent columns of adjustment patterns have an equal distance therebetween.

In some embodiments, the plurality of adjustment patterns are disposed in the electron transporting layer. The electron transporting layer has a first surface in contact with the first electrode and a second surface in contact with the quantum dot light-emitting layer. In a direction perpendicular to a plane where the first electrode is located, the plurality of adjustment patterns and the first surface have a distance therebetween, and the plurality of adjustment patterns and the second surface have another distance therebetween.

In some embodiments, the electron transporting layer includes a first electron transporting sub-layer and a second electron transporting sub-layer, and the first electron transporting sub-layer is closer to the first electrode than the second electron transporting sub-layer. The plurality of adjustment patterns are disposed between the first electron transporting sub-layer and the second electron transporting sub-layer, and at least a portion of the second electron transporting sub-layer fills a gap between the plurality of adjustment patterns and is in contact with the first electron transporting sub-layer.

In some embodiments, the plurality of adjustment patterns are disposed between the electron transporting layer and the quantum dot light-emitting layer.

In some embodiments, the quantum dot light-emitting layer is in contact with the electron transporting layer through a gap between the plurality of adjustment patterns.

In some embodiments, the number of lattice defects per unit area in a surface where the plurality of adjustment patterns in contact with the quantum dot light-emitting layer is less than the number of lattice defects per unit area in a surface of the electron transporting layer in contact with the quantum dot light-emitting layer.

In some embodiments, the plurality of adjustment patterns are disposed between the first electrode and the electron transporting layer. The electron transporting layer is in contact with the first electrode through a gap between the plurality of adjustment patterns.

In another aspect, a light-emitting device is provided. The light-emitting device includes a first electrode, an electron transporting layer, a quantum dot light-emitting layer, a second electrode and an adjustment layer. The electron transporting layer is disposed on a side of the first electrode. The quantum dot light-emitting layer is disposed on a side of the electron transporting layer away from the first electrode. The second electrode is disposed on a side of the quantum dot light-emitting layer away from the first electrode. The adjustment layer is disposed between the first electrode and the quantum dot light-emitting layer, and is in contact with the electron transporting layer. The adjustment layer is of a continuous film layer structure. The adjustment layer includes at least two two-dimensional semiconductor layers, and the at least two two-dimensional semiconductor layers form a moiré superlattice structure. The adjustment layer is configured to induce electron traps to trap electrons transmitted from the first electrode to the quantum dot light-emitting layer.

In some embodiments, an interlayer twist angle between two adjacent two-dimensional semiconductor layers is less than or equal to 10°.

In some embodiments, the electron transporting layer includes a first electron transporting sub-layer and a second electron transporting sub-layer. In a direction perpendicular to a plane in which the first electrode is located and pointing from the first electrode to the quantum dot light-emitting layer, the first electron transporting sub-layer, the adjustment layer and the second electron transporting sub-layer are sequentially stacked; or the adjustment layer is disposed between the electron transporting layer and the quantum dot light-emitting layer; or the adjustment layer is disposed between the first electrode and the electron transporting layer.

In yet another aspect, a method for manufacturing a light-emitting device is provided. The method includes forming a first electrode on a substrate; forming an electron transporting layer on a side of the first electrode away from the substrate, the electron transporting layer including an N-type inorganic semiconductor material; forming a quantum dot light-emitting layer on a side of the electron transporting layer away from the substrate; and forming a second electrode on a side of the quantum dot light-emitting layer away from the substrate. After forming the first electrode and before forming the quantum dot light-emitting layer, the method further includes: forming a plurality of adjustment patterns distributed at intervals, the plurality of adjustment patterns are each in contact with the electron transporting layer. At least a portion of an orthographic projection of the electron transporting layer on the substrate is located in a gap between orthographic projections of the plurality of adjustment patterns on the substrate.

In yet another aspect, a method for manufacturing a light-emitting device is provided. The method includes: forming a first electrode on a substrate; forming an electron transporting layer on a side of the first electrode away from the substrate, the electron transporting layer including an N-type inorganic semiconductor material; forming a quantum dot light-emitting layer on a side of the electron transporting layer away from the substrate; and forming a second electrode on a side of the quantum dot light-emitting layer away from the substrate. After forming the first electrode and before forming the quantum dot light-emitting layer, the method further includes forming an adjustment layer. The adjustment layer is in contact with the electron transporting layer. The adjustment layer is of a continuous film layer structure. The adjustment layer includes at least two two-dimensional semiconductor layers, and the at least two two-dimensional semiconductor layers form a moiré superlattice structure.

In yet another aspect, a display panel is provided. The display panel includes a backplane and a plurality of light-emitting devices. The backplane includes a substrate and a plurality of pixel circuits disposed on the substrate.

The plurality of light-emitting devices are disposed on the backplane, and the plurality of light-emitting devices are each the light-emitting device described in any of the above embodiments. A first electrode of at least one light-emitting device is closer to the backplane than a second electrode thereof, and a first electrode of a single light-emitting device is electrically connected to a pixel circuit.

In some embodiments, a distance between two adjacent light-emitting devices is a first distance. A light-emitting device includes a plurality of adjustment patterns distributed at intervals, and a distance between two adjacent adjustment patterns is a second distance. The second distance is less than or equal to the first distance.

In some embodiments, a light-emitting device has a light-emitting region, and an area of a plurality of adjustment patterns of the light-emitting device is less than or equal to an area of the light-emitting region.

In yet another aspect, a display apparatus is provided. The display apparatus includes a display panel. The display panel is the display panel described in any of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person of ordinary skill in the art can obtain other drawings according to these accompanying drawings. In addition, accompanying drawings to be described below may be regarded as schematic diagrams, and are not limitations on an actual size of a product, an actual process of a method and an actual timing of a signal involved in the embodiments of the present disclosure.

FIG. 1 is a diagram showing a structure of a display apparatus, in accordance with some embodiments;

FIG. 2 is a top view showing a structure of a display panel, in accordance with some embodiments;

FIG. 3 is a sectional view of the display panel in FIG. 2 taken along the section line Z-Z′;

FIG. 4 is a diagram showing a structure of a light-emitting device, in accordance with some embodiments;

FIG. 5A is a partial enlargement view of a region Q of the display panel in FIG. 3;

FIG. 5B is another partial enlargement view of a region Q of the display panel in FIG. 3;

FIG. 5C is yet another partial enlargement view of a region Q of the display panel in FIG. 3;

FIG. 6A is a top view showing a structure of an electron transporting layer, in accordance with some embodiments;

FIG. 6B is a top view showing a structure of another electron transporting layer, in accordance with some embodiments;

FIG. 6C is a top view showing a structure of yet another electron transporting layer, in accordance with some embodiments;

FIG. 7A is yet another partial enlargement view of a region Q of the display panel in FIG. 3;

FIG. 7B is yet another partial enlargement view of a region Q of the display panel in FIG. 3;

FIG. 7C is yet another partial enlargement view of a region Q of the display panel in FIG. 3;

FIGS. 8 to 12 are each a flowchart of a method for manufacturing a light-emitting device, in accordance with some embodiments;

FIG. 13 is a diagram showing a structure of an adjustment pattern, in accordance with some embodiments; and

FIG. 14 is a diagram showing a structure of an adjustment layer, in accordance with some embodiments.

### DETAILED DESCRIPTION

Technical solutions in some embodiments of the present disclosure will be described clearly and completely below with reference to the accompanying drawings. However, the described embodiments are merely some but not all embodiments of the present disclosure. All other embodiments obtained by a person having ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are used for descriptive purposes only, and are not to be construed as indicating or implying a relative importance or implicitly indicating the number of indicated technical features. Thus, features defined with the terms “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. The term “coupled” or “communicatively coupled”, however, may also mean that two or more components are not in direct contact with each other, but still cooperate or interact with each other. The embodiments disclosed herein are not necessarily limited to the content herein.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, depending on the context, the term “if” is optionally construed as “when”, “in a case where”, “in response to determining” or “in response to detecting”. Similarly, depending on the context, the phrase “if it is determined” or “if [a stated condition or event] is detected” is optionally construed as “in a case where it is determined”, “in response to determining”, “in a case where [the stated condition or event] is detected”, or “in response to detecting [the stated condition or event]”.

In addition, the use of the phrase “based on” is meant to be open and inclusive, since a process, step, calculation or other action that is “based on” one or more of the stated conditions or values may, in practice, be based on additional conditions or values beyond those stated.

The term such as “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of a measurement system).

The term such as “parallel”, “perpendicular” or “equal” as used herein includes a stated condition and a condition similar to the stated condition, and a range of the similar condition is within an acceptable range of deviation. The acceptable range of deviation is determined is determined by a person of ordinary skill in the art in consideration of the measurement in question and errors associated with the measurement of a specific quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be that a difference between two equals is less than or equal to 5% of either of the two equals.

It will be understood that, when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but as including deviations in shape due to, for example, manufacturing. For example, an etched region shown in a rectangular shape generally has a feature of being curved. Therefore, the regions shown in the accompanying drawings are schematic in nature, and their shapes are not intended to show actual shapes of regions in an apparatus, and are not intended to limit the scope of the exemplary embodiments.

Some embodiments of the present disclosure provide light-emitting devices 11 and methods for manufacturing the same, a display panel 10 and a display apparatus 100. The light-emitting devices 11 and the methods for manufacturing the same, the display panel 10 and the display apparatus 100 will be described below.

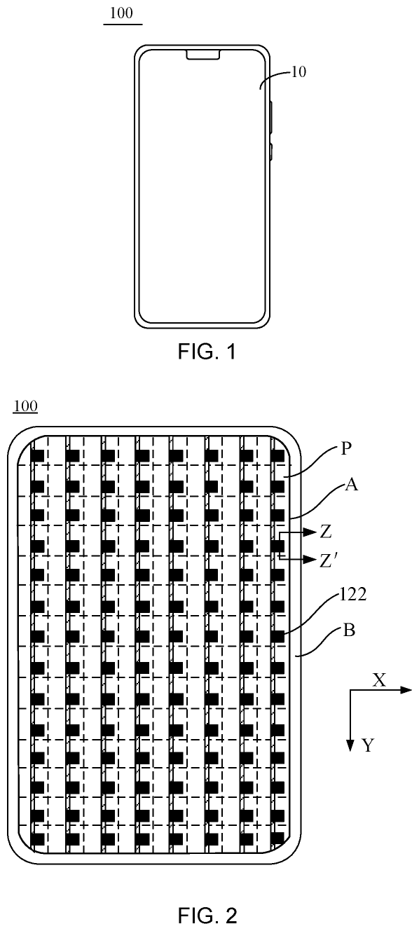

As shown in FIG. 1, some embodiments of the present disclosure provide a display apparatus 100, and the display apparatus 100 may be any apparatus that displays images whether in motion (e.g., videos) or stationary (e.g., still images), and regardless of text or image. More specifically, it is anticipated that the described embodiments may be implemented in or associated with a variety of electronic apparatuses such as (but not limited to), mobile phones, wireless apparatuses, personal digital assistants, hand-held or portable computers, global positioning system (GPS) receivers/navigators, cameras, video players, video cameras, game consoles, watches, clocks, calculators, television monitors, flat panel displays, computer monitors, automobile displays (e.g., odometer displays), navigators, cockpit controllers and/or displays, displays of camera view (e.g., displays of rear-view camera in vehicles), electronic photographs, electronic billboards or signs, projectors, architectural structures, packaging and aesthetic structures (e.g., displays for displaying an image of a piece of jewelry).

In some embodiments, as shown in FIG. 1, the display apparatus 100 includes a display panel 10, which is a quantum dot light-emitting diode (QLED) display panel.

As shown in FIG. 2, the display panel 10 has a display region A and a peripheral region B located on at least one side of the display region A. FIG. 2 illustrates an example in which the peripheral region B surrounds the display region A.

The display region A is a region for displaying images, and the display region A is configured to provide sub-pixels P therein. The peripheral region B is a region which is not used for displaying images, and the peripheral region B may be configured to provide scan driving circuits, circuit traces and bonding pins therein.

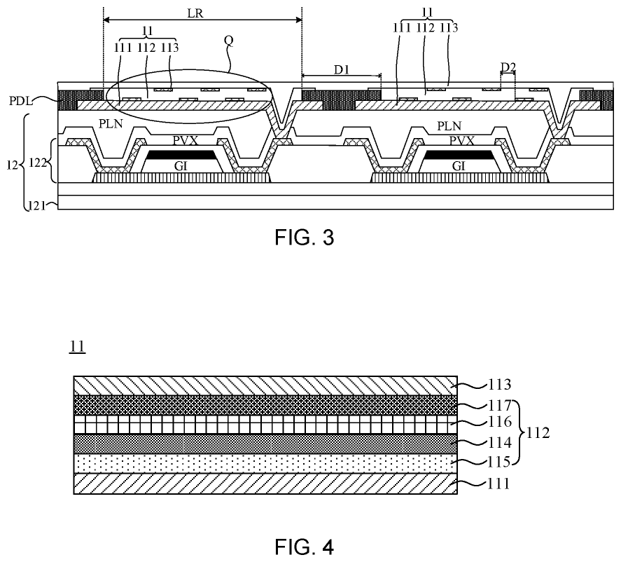

For example, as shown in FIGS. 2 and 3, the display panel 10 includes a plurality of sub-pixels P disposed on a side of a substrate 121 and located in the display region A. The plurality of sub-pixels P are arranged in a plurality of rows and a plurality of columns, and each row of sub-pixels P may include sub-pixels P arranged in a second direction X, and each column of sub-pixels P may include sub-pixels P arranged in a first direction Y.

In some embodiments, as shown in FIG. 3, the display panel 10 includes light-emitting devices 11 and a backplane (BP) 12. The backplane 12 includes the substrate 121 and a plurality of pixel circuits 122, and the plurality of pixel circuits 122 are disposed on the substrate 121. As shown in FIGS. 2 and 3, each sub-pixel P includes a light-emitting device 11 and a pixel circuit 122.

As shown in FIG. 3, the pixel circuit 122 includes a plurality of thin film transistors. A thin film transistor includes an active layer, a source, a drain and a gate, and the source and the drain are each in contact with the active layer.

As shown in FIG. 3, in a direction perpendicular to the substrate 121 and pointing from the pixel circuit 122 to the light-emitting device 11, the light-emitting device 11 includes a first electrode 111, a light-emitting functional layer 112 and a second electrode 113 that are arranged in sequence. That is, the first electrode 111 is closer to the backplane 12 than the second electrode 113, the light-emitting functional layer 112 is disposed on a side of the first electrode 111 away from the backplane 12, and the second electrode 113 is disposed on a side of the light-emitting functional layer 112 away from the first electrode 111.

In some embodiments, the first electrode 111 is electrically connected to a source or drain of a driving transistor in the pixel circuit 122, and the first electrode 111 is an anode and the second electrode 113 is a cathode (i.e., the light-emitting device 11 having an upright structure). In some other embodiments, the first electrode 111 is electrically connected to the source or drain of the driving transistor in the pixel circuit 122, and the first electrode 111 is the cathode and the second electrode 113 is the anode (i.e., the light-emitting device 11 having an inverted structure).

As shown in FIGS. 3 and 4, the light-emitting functional layer 112 includes a quantum dot light-emitting layer 114 and an electron transporting layer (ETL) 115, and the light-emitting functional layer 112 further includes a hole transporting layer (HTL) 116 and/or a hole injection layer (HIL) 117.

It can be understood that, a stacking direction of film layers included in the light-emitting functional layer 112 in the upright structure is opposite to a stacking direction of film layers included in the light-emitting functional layer 112 in the inverted structure. A schematic description will be made below by considering an example where the light-emitting functional layer 112 includes the electron transporting layer 115, the quantum dot light-emitting layer 114, the hole transporting layer 116 and the hole injection layer 117.

In the upright structure, the hole injection layer 117 is disposed on a side of the first electrode 111 proximate to the second electrode 113, the hole transporting layer 116 is disposed on a side of the hole injection layer 117 away from the first electrode 111, the quantum dot light-emitting layer 114 is disposed on a side of the hole transporting layer 116 away from the first electrode 111, and the electron transporting layer 115 is disposed on a side of the quantum dot light-emitting layer 114 away from the first electrode 111.

In the inverted structure, as shown in FIG. 4, the electron transporting layer 115 is disposed on a side of the first electrode 111 proximate to the second electrode 113, the quantum dot light-emitting layer 114 is disposed on a side of the electron transporting layer 115 away from the first electrode 111, the hole transporting layer 116 is disposed on a side of the quantum dot light-emitting layer 114 away from the first electrode 111, and the hole injection layer 117 is disposed on a side of the hole transporting layer 116 away from the first electrode 111.

As shown in FIGS. 3 and 4, the display panel 10 further includes a pixel defining layer PDL. The pixel defining layer PDL is disposed on a side of the plurality of pixel circuits 122 away from the substrate 121. The pixel defining layer PDL is provided with a plurality of openings therein, and at least a portion of the quantum dot light-emitting layer 114 of a light-emitting device 11 is located in an opening, and the opening defines a light-emitting region LR of the corresponding light-emitting device 11.

In the related art, before forming the film layers between the first electrode 111 and the second electrode 113 by inkjet printing, a pixel defining layer PDL is formed in advance, and the ink used to form the light-emitting functional layer 112 may cover sidewalls of the openings of the pixel defining layer PDL and an upper portion of the pixel defining layer PDL, which may greatly affect the topography and thickness uniformity of the light-emitting functional layer 112, and greatly affect the performance and uniformity of the light-emitting devices 11, and thus affect the mass production of quantum dot light-emitting diodes.

In order to alleviate the problem of non-uniform thickness of the film layers between the first electrode 111 and the second electrode 113, the electron transporting layer 115 is formed by using a sputtering process. However, the electron transporting layer 115 formed by the sputtering process has a high material mobility and is injected with a large number of electrons, which may affect carrier balance and thus lead to gathering of excess charges in the quantum dot light-emitting layer 114. Photons may transfer energy to free charges near the photons, thereby resulting in non-radiative recombination. As a result, quantum yield may be reduced and ultimately light emitting efficiency of the light-emitting device 11 may be affected.

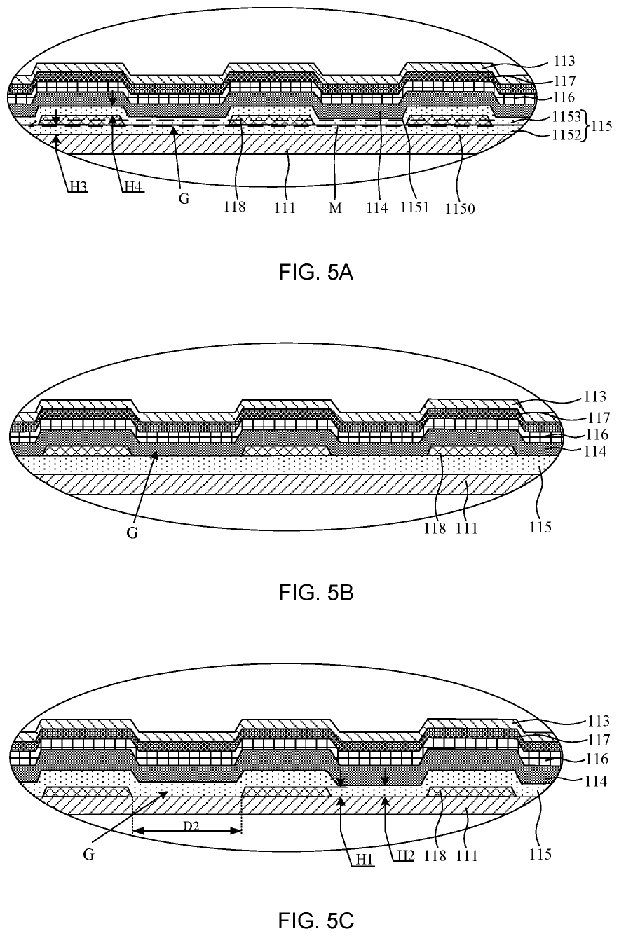

Based on this, in the light-emitting device 11 provided by some embodiments of the present disclosure, as shown in FIG. 5A, the light-emitting device 11 further includes a plurality of adjustment patterns 118. Orthographic projections of the plurality of adjustment patterns 118 on a reference plane M are distributed at intervals. The reference plane M is parallel to a plane in which the first electrode 111 is located.

As shown in FIGS. 3 and 5A, the plurality of adjustment patterns may be distributed on the same reference plane M, or on different reference planes M. That is, the plurality of adjustment patterns 118 and the first electrode 111 may have equal or unequal distances therebetween, which may be selected according to actual needs, and is not limited in the embodiments of the present disclosure.

The plurality of adjustment patterns 118 are disposed between the first electrode 111 and the quantum dot light-emitting layer 114 and are each in contact with the electron transporting layer 115. At least a portion of an orthographic projection of the electron transporting layer 115 on the reference plane M is located in a gap between the orthographic projections of the plurality of adjustment patterns 118 on the reference plane M. The plurality of adjustment patterns 118 are configured to block electrons transmitted from the first electrode 111 to the quantum dot light-emitting layer 114, or to induce electron traps to trap the electrons transmitted from the first electrode 111 to the quantum dot light-emitting layer 114. That is, the light-emitting device 11 can block or trap the electrons transmitted from the first electrode 111 to the quantum dot light-emitting layer 114 through the plurality of adjustment patterns 118, thereby reducing the electronic transportability, increasing the carrier balance, and reducing the accumulation of surplus electrons in the quantum dots.

It can be seen from the above that, in the embodiments of the present disclosure, the plurality of adjustment patterns 118 between the first electrode 111 and the quantum dot light-emitting layer 114 can block the electrons transmitted from the first electrode 111 to the quantum dot light-emitting layer 114, or induce the electron traps to trap the electrons transmitted from the first electrode 111 to the quantum dot light-emitting layer 114. In this way, in a case where it is ensured that the electrons still have a transmission channel (i.e., in a case where the plurality of adjustment patterns 118 do not block the electron transmission completely), the electron transmission channels may be reduced and the electron transmission capacity may be reduced. Eventually, the luminous efficiency of the light-emitting device 11 may be improved.

In some embodiments, an area of the plurality of adjustment patterns 118 is less than or equal to an area of the light-emitting region of the light-emitting device 11. In addition, the plurality of adjustment patterns 118 may be made of the same material as the hole transporting layer 116.

In some embodiments, the plurality of adjustment patterns 118 include an insulating transparent oxide material, and the transparent oxide material is an insulating material with a band gap more than 4 eV, a lowest unoccupied molecular orbital (LUMO) level shallower than −3 eV, and a highest occupied molecular orbital (HOMO) level deeper than −7 eV. In addition, the insulating transparent oxide material has a charge mobility less than or equal to 10-6 cm²/(V·s), which may reduce the electronic transportability by blocking electrons.

For example, the plurality of adjustment patterns 118 include at least one of silicon oxide, silicon nitride and silicon oxynitride. It will be noted that the silicon oxide includes silicon monoxide (SiO), silicon dioxide (SiO₂) and Si₂O₆, which are not limited in the embodiments of the present disclosure.

In some other embodiments, the plurality of adjustment patterns 118 include a hole-transporting-type transparent oxide material. A lowest unoccupied molecular orbital level of the hole-transporting-type transparent oxide material is shallower than a lowest unoccupied molecular orbital level of the electron transporting layer 115. The hole-transporting-type transparent oxide material can trap electrons and serve as the electron traps to reduce the electronic transportability.

For example, the plurality of adjustment patterns 118 include at least one of oxide of molybdenum, oxide of nickel, oxide of zirconium and oxide of vanadium, which are not limited in the embodiments of the present disclosure.

It will be noted that the oxide of molybdenum includes molybdenum oxide, molybdenum dioxide and molybdenum trioxide; the oxide of nickel includes nickel oxide and nickel sesquioxide; the oxide of zirconium includes zirconium dioxide; and the oxide of vanadium includes vanadium monoxide, vanadium trioxide, vanadium dioxide and vanadium pentoxide. The embodiments of the present disclosure are not limited thereto.

In yet some other embodiments, as shown in FIG. 13, the plurality of adjustment patterns 118 include at least two two-dimensional semiconductor layers 1180. The at least two two-dimensional semiconductor layers form a moiré superlattice structure. The plurality of adjustment patterns 118 may induce the electron traps to confine the electrons in the superlattice structure. In this way, the electronic transportability may be reduced.

It will be noted that the moiré superlattice structure is a coupling structure between two incoherent and mutually rotatable crystals which are realized by at least two layers of two-dimensional materials being assembled through vertical stacking due to the action of Van der Waals' force between the layers. The moiré superlattice structure may be formed by homogeneous materials layers of different angles or by lattice mismatch of heterogeneous materials.

It will be noted that the principle of the moiré superlattice structure is as follows: when atomically-thin crystals are assembled (a thickness of an atomically-thin single layer is generally in a range of 3 Å to 5 Å, e.g., a thickness of a single-layer graphene is 3.5 Å), lattice mismatch and rotation between layers may lead to different moiré superlattice structures. The reciprocal space of the moiré superlattice structure has a direct impact on the momentum space, and the interlayer interaction may change phonon modes and charge distribution, so that the energy band structure and charge distribution of the moiré superlattice structure may be modulated. By considering the homogeneous graphene as an example, in a case where an interlayer twist angle between layers is relatively small (less than 5°), an interlayer coupling is strong, especially in a case where the twist angle is close to a magic angle (1.1°), electron motion becomes slow and electrons may be approximately seen as being localized in the superlattice. In addition, by constructing superlattices between structures such as boron alkene, graphene/boron nitride, transition metal dichalcogenides (TMDs) and corresponding heterostructures thereof, the energy band structure and electronic properties of the moiré superlattice structure may also be modulated. For different two-dimensional materials, angles between layers needs to be different to have the strongest effect on electrons, and generally the angles are not more than 10°, and most of the angles are less than 5°. For example, an optimal angle for double-layer graphene is 1.1°, and an optimal angle for graphene/boron nitride is 2°.

For example, the at least two two-dimensional semiconductor layers include a combination of at least two of tungsten disulfide (WS₂), tungsten diselenide (WSe₂), molybdenum selenide, tungsten sulfide, graphene, boron alkene, boron nitride, and spiral bismuth oxychloride (BiOCl) nanosheets, which are not specifically limited in the embodiments of the present disclosure.

In some embodiments, as shown in FIG. 5A, a surface of the second electrode 113 away from the first electrode 111 has undulating topography, so as to improve the light-emitting efficiency of the light-emitting device 11.

That the surface of the second electrode 113 away from the first electrode 111 has the undulating topography means that the surface of the second electrode 113 away from the first electrode 111 is an uneven surface. For example, the surface of the second electrode 113 away from the first electrode 111 has a plurality of protrusions, and each protrusion corresponds to an adjustment pattern 118, so that a light-exiting surface of the light-emitting device 11 (the surface of the second electrode 113 away from the first electrode 111) presents a certain curved surface structure, thereby improving the light-emitting efficiency of the light-emitting device 11.

In some embodiments, as shown in FIG. 5A, the plurality of adjustment patterns 118 are disposed in the electron transporting layer 115. The electron transporting layer 115 includes a first surface 1150 in contact with the first electrode 111, and a second surface 1151 in contact with the quantum dot light-emitting layer 114. There is a distance H3 between the plurality of adjustment patterns 118 and the first surface 1150, and there is a distance H4 between the plurality of adjustment patterns 118 and the second surface 1151.

As shown in FIG. 5A, the electron transporting layer 115 includes a first electron transporting sub-layer 1152 and a second electron transporting sub-layer 1153, and the first transporting sub-layer 1152 is closer to the first electrode 111 than the second electron transporting sub-layer 1153. The plurality of adjustment patterns 118 are located between the first electron transporting sub-layer 1152 and the second electron transporting sub-layer 1153, and at least a portion of the second electron transporting sub-layer 1153 fills a gap G between the plurality of adjustment patterns 118 and is in contact with the first electron transporting sub-layer 1152.

In some other embodiments, as shown in FIG. 5B, the plurality of adjustment patterns 118 are disposed between the electron transporting layer 115 and the quantum dot light-emitting layer 114. The quantum dot light-emitting layer 114 is in contact with the electron transporting layer 115 through the gap G between the plurality of adjustment patterns 118. The plurality of adjustment patterns 118 are located between the electron transporting layer 115 and the quantum dot light-emitting layer 114 such that the plurality of adjustment patterns 118 may serve as the electron traps to reduce electronic transportability. In addition, lattice defects may cause quenching of the quantum dot light-emitting layer 114, and the number of lattice defects per unit area in a surface of the plurality of adjustment patterns 118 in contact with the quantum dot light-emitting layer 114 is less than the number of lattice defects per unit area in a surface of the electron transporting layer 115 in contact with the quantum dot light-emitting layer 114. Therefore, the plurality of adjustment patterns 118 disposed between the electron transporting layer 115 and the quantum dot light-emitting layer 114 may also serve as a passivation layer, so as to reduce the quenching effect of a film layer in contact with the quantum dot light-emitting layer 114 on the quantum dot light-emitting layer 114 by reducing a contact area between the electron transporting layer 115 and the quantum dot light-emitting layer 114.

For example, a material of the electron transporting layer 115 may be zinc oxide, and a material of the adjustment patterns 118 may be silicon monoxide, so that the number of the lattice defects per unit area in the surface of the adjustment patterns 118 in contact with the quantum dot light-emitting layer 114 is much less than the number of the lattice defects per unit area in the surface of the electron transporting layer 115 in contact with the quantum dot light-emitting layer 114. As a result, the quenching effect of the film layer in contact with the quantum dot light-emitting layer 114 on the quantum dot light-emitting layer 114 may be significantly reduced.

A contact area between the adjustment patterns 118 and the quantum dot light-emitting layer 114 may be 30% to 70% of an area of the quantum dot light-emitting layer 114, and the contact area between the electron transporting layer 115 and the quantum dot light-emitting layer 114 may be 30% to 70% of the area of the quantum dot light-emitting layer 114. For example, the contact area between the adjustment patterns 118 and the quantum dot light-emitting layer 114 is 30% of the area of the quantum dot light-emitting layer 114, and the contact area between the electron transporting layer 115 and the quantum dot light-emitting layer 114 is 70% of the area of the quantum dot light-emitting layer 114. For another example, the contact area between the adjustment patterns 118 and the quantum dot light-emitting layer 114 is 70% of the area of the quantum dot light-emitting layer 114, and the contact area between the electron transporting layer 115 and the quantum dot light-emitting layer 114 is 30% of the area of the quantum dot light-emitting layer 114.

In yet some other embodiments, as shown in FIG. 5C, the plurality of adjustment patterns 118 are disposed between the first electrode 111 and the electron transporting layer 115. The electron transporting layer 115 is in contact with the first electrode 111 through the gap G between the plurality of adjustment patterns 118.

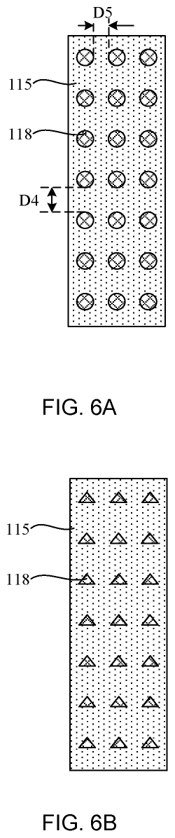

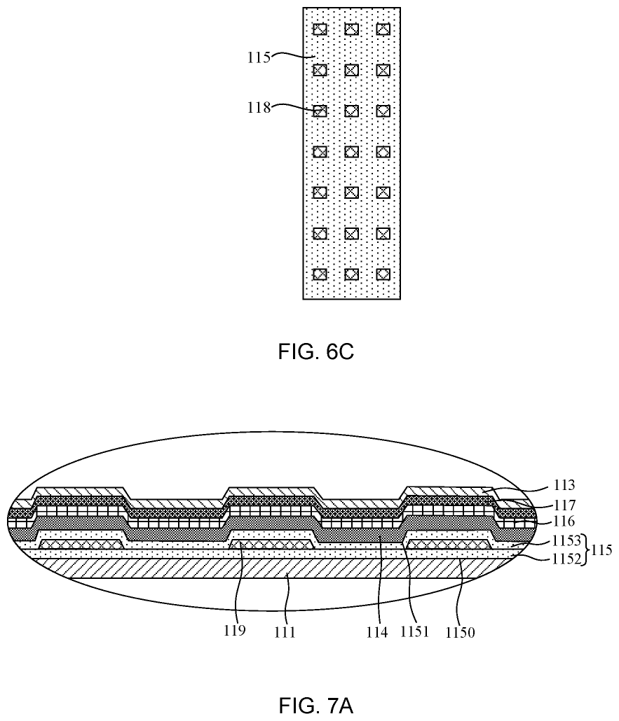

In some embodiments, as shown in FIG. 6A, a shape of an orthographic projection of at least one adjustment pattern 118 on the reference plane M is a circle. In some other embodiments, as shown in FIG. 6B, a shape of the orthographic projection of the at least one adjustment pattern 118 on the reference plane M is a triangle. In yet some other embodiments, as shown in FIG. 6C, the shape of the orthographic projection of the at least one adjustment pattern 118 on the reference plane M is a regular quadrilateral. In addition, the adjustment pattern 118 may also be a rhombus, a trapezoid or an ellipse, which are not limited in the embodiments of the present disclosure. Adjustment patterns 118 with various shapes are all able to increase the roughness of an interface between film layers, which may reduce the proportion of an optical waveguide mode and increase the proportion of light output.

Based on the above, as shown in FIGS. 6A, 6B and 6C, the plurality of adjustment patterns 118 may be arranged in a plurality of rows and a plurality of columns. Any two adjacent rows of adjustment patterns 118 have an equal distance D4 therebetween, and/or any two adjacent columns of adjustment patterns 118 have an equal distance D5 therebetween.

As shown in FIG. 5C, a thickness H1 of an adjustment pattern 118 is in a range from 0.5 nm to 20 nm. This range needs to take into account a thickness of a single atomic layer. A thickness H2 of the electron transporting layer 115 is in a range from 20 nm to 60 nm. Therefore, the thickness H1 of the adjustment pattern 118 is not more than 20 nm, so as to ensure that the adjustment pattern 118 does not affect the overall conductive channel of the light-emitting device 11. A distance D2 between adjacent adjustment patterns 118 is in a range from 0.5 μm to 20 μm, and the distance D2 takes into account a pixel size, which is approximately 10 μm for a pixel of 500 pixels per inch (ppi) and 20 μm for a pixel of 300 ppi, and the distance D2 is not more than the pixel size. In addition, an area of the adjustment pattern 118 is approximately 5% to 50% of a QLED pixel size.

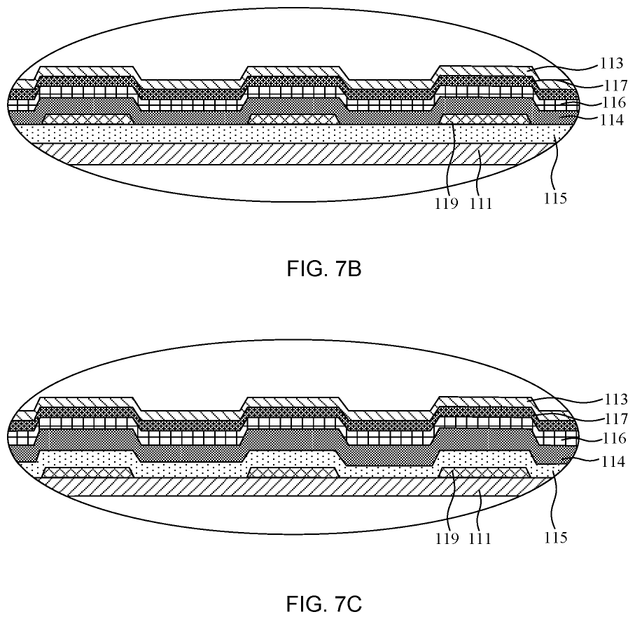

The embodiments of the present disclosure further provide a light-emitting device 11. The light-emitting device 11 includes an adjustment layer 119. As shown in FIG. 7A, the light-emitting device 11 includes a first electrode 111, an electron transporting layer 115, a quantum dot light-emitting layer 114, a hole transporting layer 116, a hole injection layer 117, a second electrode 113 and the adjustment layer 119. The electron transporting layer 115 is disposed on a side of the first electrode 111. The quantum dot light-emitting layer 114 is disposed on a side of the electron transporting layer 115 away from the first electrode 111. The hole transporting layer 116 is disposed on a side of the quantum dot light-emitting layer 114 away from the first electrode 111. The hole injection layer 117 is disposed on a side of the hole transporting layer 116 away from the first electrode 111. The second electrode 113 is disposed on a side of the hole injection layer 117 away from the first electrode 111. The adjustment layer 119 is disposed between the first electrode 111 and the quantum dot light-emitting layer 114, and is in contact with the electron transporting layer 115. The adjustment layer 119 is of a continuous film layer structure, and as shown in FIG. 14, the adjustment layer 119 includes at least two two-dimensional semiconductor layers 1090. The at least two two-dimensional semiconductor layers form a moiré superlattice structure. The adjustment layer 119 is configured to induce electron traps to trap electrons transmitted from the first electrode 111 to the quantum dot light-emitting layer 114. The adjustment layer 119 induces the electron traps to confine the electrons in the superlattice structure, so as to reduce the electronic transportability and improve the luminous efficiency of the light-emitting device 11.

It will be noted that the moiré superlattice structure may confine the electrons in the superlattice structure, thereby reducing the electronic transportability without blocking electron transport completely.

In some embodiments, the adjustment layer 119 includes a combination of at least two of tungsten disulfide, tungsten diselenide, molybdenum selenide, tungsten sulfide, graphene, boron alkene, boron nitride, and spiral bismuth oxychloride nanosheets, which are not limited in the embodiments of the present disclosure.

In some embodiments, an interlayer twist angle between two adjacent two-dimensional semiconductor layers is less than or equal to 10°, so as to impose the strongest confinement to electrons.

In some embodiments, as shown in FIG. 7A, the electron transporting layer 115 includes a first electron transporting sub-layer 1152 and a second electron transporting sub-layer 1153. In a direction perpendicular to a plane in which the first electrode 111 is located and pointing from the first electrode 111 to the quantum dot light-emitting layer 114, the first electron transporting sub-layer 1152, the adjustment layer 119 and the second electron transporting sub-layer 1153 are sequentially stacked.

In some other embodiments, as shown in FIG. 7B, the adjustment layer 119 is disposed between the electron transporting layer 115 and the quantum dot light-emitting layer 114. The adjustment layer 119 may serve as the electron traps to reduce electronic transportability, and may also reduce a contact area between the electron transporting layer 115 and the quantum dot light-emitting layer 114, and reduce the quenching effect of the electron transporting layer 115 on the quantum dot light-emitting layer 114. In addition, lattice defects may cause quenching of the quantum dot light-emitting layer 114, and the number of lattice defects per unit area in a surface of the adjustment layer 119 in contact with the quantum dot light-emitting layer 114 is less than the number of lattice defects per unit area in the surface of the electron transporting layer 115 in contact with the quantum dot light-emitting layer 114. Therefore, the adjustment layer 119 disposed between the electron transporting layer 115 and the quantum dot light-emitting layer 114 may also serve as a passivation layer, so as to reduce the quenching effect of a film layer in contact with the quantum dot light-emitting layer 114 on the quantum dot light-emitting layer 114 by reducing the contact area between the electron transporting layer 115 and the quantum dot light-emitting layer 114.

In yet some other embodiments, as shown in FIG. 7C, the adjustment layer 119 is disposed between the first electrode 111 and the electron transporting layer 115.

The display panel 10 provided in embodiments of the present disclosure includes the light-emitting device 11 described in any of the above embodiments.

As shown in FIG. 3, in a case where the light-emitting devices 11 each include a plurality of adjustment patterns 118, a distance between two adjacent light-emitting devices 11 is a first distance D1, and a distance between two adjacent adjustment patterns 118 is a second distance D2. The second distance D2 is less than or equal to the first distance D1.

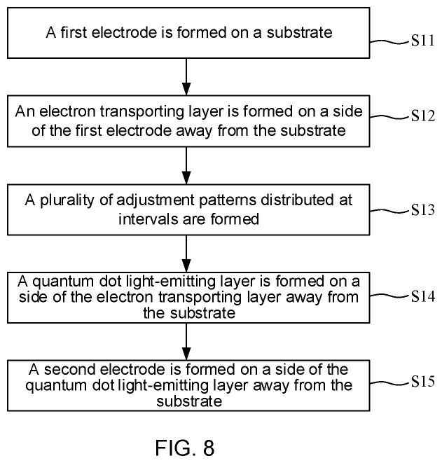

The method for manufacturing the light-emitting device 11 provided in some embodiments of the present disclosure includes, as shown in FIG. 8, steps S11 to S15.

In S11, a first electrode 111 is formed on a substrate.

For example, a first conductive layer is formed on a surface of the substrate by coating or chemical deposition, and a plurality of first electrodes 111 are formed by performing mask exposure, development and etching processes on the first conductive layer.

A material of the first conductive layer may be glass, polyethylene terephthalate (PET), transparent indium tin oxide (ITO), fluorine-doped tin dioxide (F-doped SnO₂, FTO film), or a conductive polymer, etc., or may be an opaque metal electrode such as aluminum (Al) or silver (Ag), and the embodiments of the present disclosure are not limited thereto.

In S12, an electron transporting layer 115 is formed on a side of the first electrode 111 away from the substrate, and the electron transporting layer 115 includes an N-type inorganic semiconductor material.

For example, the electron transporting layer 115 may be formed by using a sol-gel method, a nanoparticle spin coating method or a sputtering process. For example, the electron transporting layer 115 is formed by using the sputtering process. The electron transporting layer 115 is an N-type inorganic semiconductor film. The N-type inorganic semiconductor film includes zinc oxide or a zinc oxide (ZnO) film doped with magnesium (Mg), aluminum (Al), zirconium (Zr), yttrium (Y), etc., and has a thickness of 50 nm to 300 nm. The embodiments of the present disclosure are not limited thereto.

In some embodiments, a surface roughness of the electron transporting layer 115 is less than a surface roughness of a quantum dot light-emitting layer 114. In this way, the electronic transportability may be reduced and the luminous efficiency of the light-emitting device 11 may be improved. The electron transporting layer 115 may be formed by using the sputtering process, and the surface roughness of the electron transporting layer 115 formed by the sputtering process is less than 3 nm.

In S14, the quantum dot light-emitting layer 114 is formed on a side of the electron transporting layer 115 away from the substrate.

For example, the quantum dot light-emitting layer 114 may be formed by inkjet printing. A thickness of the quantum dot light-emitting layer 114 is in a range from 20 nm to 50 nm, and the embodiments of the present disclosure are not limited thereto.

In S15, a second electrode 113 is formed on a side of the quantum dot light-emitting layer 114 away from the substrate.

For example, a second conductive layer is formed on a side of the quantum dot light-emitting layer 114 away from the substrate by coating or chemical deposition, and a plurality of second electrodes 113 are formed by performing mask exposure, development and etching processes on the second conductive layer.

The second conductive layer may be made of a metal such as aluminum (Al) or silver (Ag) or may be indium zinc oxide (IZO) deposited by magnetron sputtering, and has a thickness of 10 nm to 100 nm. The embodiments of the present disclosure are not limited thereto.

Between S11 and S14, the above method further includes a step S13.

In S13, a plurality of adjustment patterns 118 distributed at intervals are formed.

In the above step, the plurality of adjustment patterns 118 are each in contact with the electron transporting layer 115. At least a portion of an orthographic projection of the electron transporting layer 115 on the substrate is located in a gap between orthographic projections of the plurality of adjustment patterns 118 on the substrate.

For example, the plurality of adjustment patterns 118 may be formed by direct deposition by using a mask, or by means of mask exposure, development and etching.

S13 may be before S12 or after S12, which is not specifically limited in the present disclosure.

It will be seen from the above that the first electrode 111 is closer to a backplane 12 than the second electrode 113, and the first electrode 111 of the light-emitting device 11 is electrically connected to a pixel circuit 122, so as to form an inverted structure. In this way, the electron transporting layer 115 is formed by using the sputtering method, and afterwards the quantum dot light-emitting layer 114 is formed by inkjet printing. The electron transporting layer 115 formed by the sputtering method does not cover sidewalls of openings of a pixel defining layer PDL and an upper portion of the pixel defining layer PDL, and a thickness of the electron transporting layer 115 is uniform. Therefore, the uniformity of the thickness of the quantum dot light-emitting layer 114 formed by a subsequent process may be improved, and thus the performance of the light-emitting device 11 may be improved.

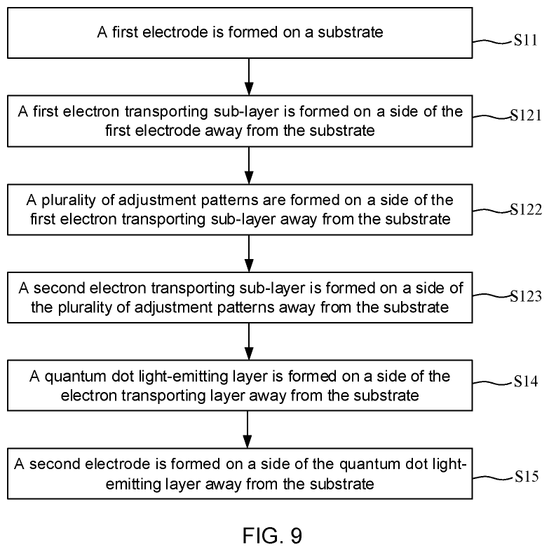

In some embodiments, as shown in FIG. 9, forming the electron transporting layer 115 and the plurality of adjustment patterns 118 include steps S121, S122 and S123.

In S121, a first electron transporting sub-layer 1152 is formed on the side of the first electrodes 111 away from the substrate.

For example, the first electron transporting sub-layer 1152 may be formed by using the sol-gel method, the nanoparticle spin coating method or the sputtering process. For example, the first electron transporting sub-layer 1152 may be formed by using the sputtering process. The first electron transporting sub-layer 1152 is an N-type inorganic semiconductor film. The N-type inorganic semiconductor film includes zinc oxide or a zinc oxide (ZnO) film doped with magnesium (Mg), aluminum (AI), zirconium (Zr), yttrium (Y), etc. The embodiments of the present disclosure are not limited thereto.

In S122, the plurality of adjustment patterns 118 are formed on a side of the first electron transporting sub-layer 1152 away from the substrate.

For example, the plurality of adjustment patterns 118 may be formed by direct deposition using a mask, or by means of mask exposure, development and etching.

In S123, a second electron transporting sub-layer 1153 is formed on a side of the plurality of adjustment patterns 118 away from the substrate. The first electron transporting sub-layer 1152 and the second electron transporting sub-layer 1153 constitute the electron transporting layer 115.

For example, the second electron transporting sub-layer 1153 is an N-type inorganic semiconductor film. The N-type inorganic semiconductor film includes zinc oxide or a zinc oxide (ZnO) film doped with magnesium (Mg), aluminum (Al), zirconium (Zr), yttrium (Y), etc. The embodiments of the present disclosure are not limited thereto. In addition, the second electron transporting sub-layer 1153 may be deposited by magnetron sputtering to a certain thickness as needed.

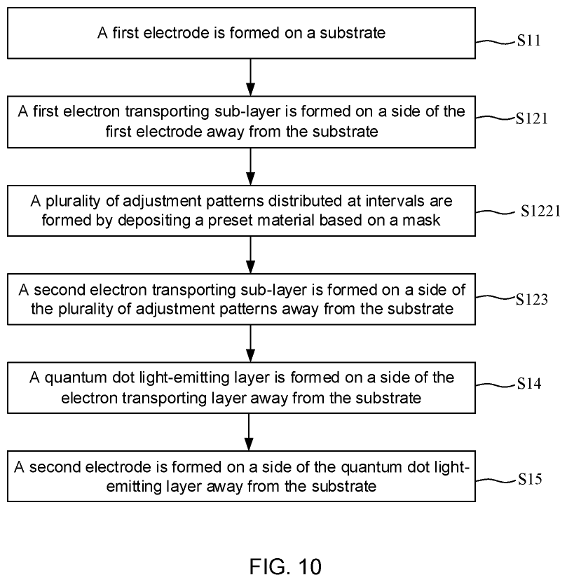

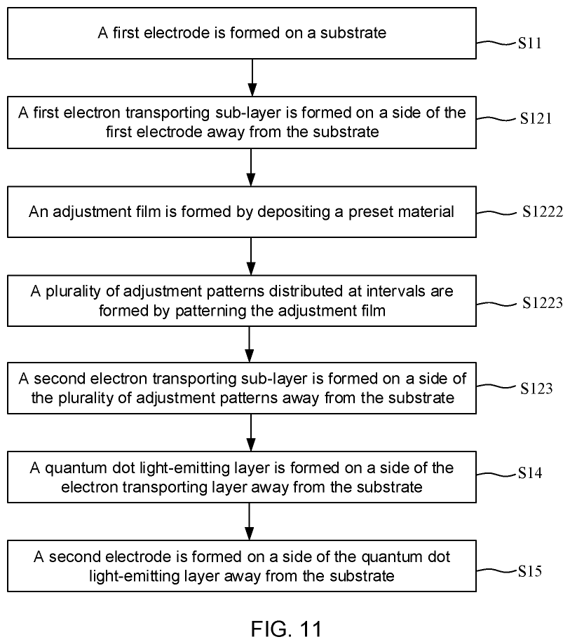

In some embodiments, as shown in FIGS. 10 and 11, S122 includes a step S1221, or includes steps S1222 to S1223.

In S1221, the plurality of adjustment patterns 118 distributed at intervals are formed by depositing a preset material based on a mask.

The preset material is a material of the adjustment patterns 118. For details, reference may be made to the above, and the embodiments of the present disclosure will not repeat here.

In S1222, an adjustment film is formed by depositing a preset material.

The preset material is a material of the adjustment patterns 118. For details, reference may be made to the above, and the embodiments of the present disclosure will not repeat here.

In S1223, the plurality of adjustment patterns 118 distributed at intervals are formed by patterning the adjustment film.

For example, the plurality of adjustment patterns 118 are formed by performing mask exposure, development and etching processes on the adjustment film.

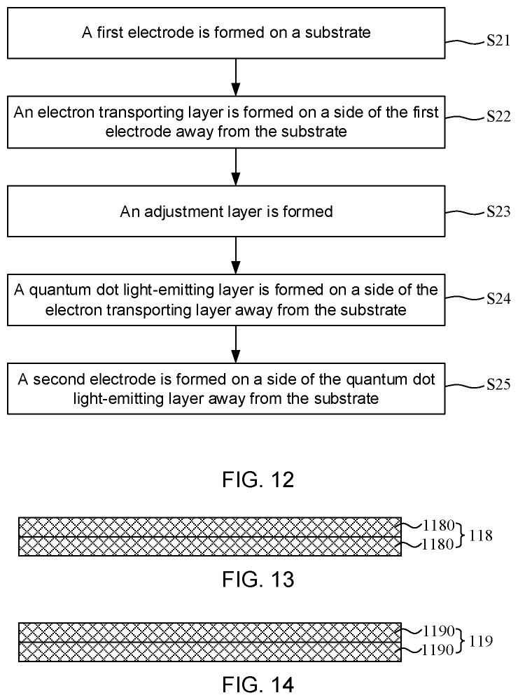

In some other embodiments, as shown in FIG. 12, the method for manufacturing the light-emitting device 11 provided in some embodiments of the present disclosure includes steps S21 to S24.

In S21, a first electrode 111 is formed on a substrate.

For example, a first conductive layer is formed on a surface of the substrate by coating or chemical deposition, and a plurality of first electrodes 111 are formed by performing mask exposure, development and etching processes on the first conductive layer.

A material of the first conductive layer may be glass, polyethylene terephthalate (PET), transparent indium tin oxide (ITO), fluorine-doped tin dioxide (F-doped SnO₂, FTO film), or a conductive polymer, etc., or may be an opaque metal electrode such as aluminum (Al) or silver (Ag), and the embodiments of the present disclosure are not limited thereto.

In S22, an electron transporting layer 115 is formed on a side of the first electrode 111 away from the substrate.

For example, the electron transporting layer 115 may be formed by using a sol-gel method, a nanoparticle spin coating method or a sputtering process. For example, the electron transporting layer 115 is formed by using the sputtering process. The electron transporting layer 115 is an N-type inorganic semiconductor film. The N-type inorganic semiconductor film includes zinc oxide or a zinc oxide (ZnO) film doped with magnesium (Mg), aluminum (Al), zirconium (Zr), yttrium (Y), etc., and has a thickness of 50 nm to 300 nm. The embodiments of the present disclosure are not limited thereto.

In S24, a quantum dot light-emitting layer 114 is formed on a side of the electron transporting layer 115 away from the substrate.

For example, a thickness of the quantum dot light-emitting layer 114 is in a range from 20 nm to 50 nm, and various thicknesses may be obtained by inkjet printing or the like as needed. The embodiments of the present disclosure are not limited thereto.

The first electrode 111 of the light-emitting device 11 is electrically connected to a pixel circuit 122, so as to form an inverted structure. In this way, the uniformity of the thickness of the quantum dot light-emitting layer 114 may be improved. In addition, only the electron transporting layer 115 formed by sputtering is provided on a side of the quantum dot light-emitting layer 114 proximate to the first electrode 111, so as to solve the problem that ink covers sidewalls of openings of a pixel defining layer PDL and an upper portion of the pixel defining layer PDL when the quantum dot light-emitting layer 114 is formed by inkjet printing.

In S25, a second electrode 113 is formed on a side of the quantum dot light-emitting layer 114 away from the substrate.

For example, the second electrode 113 may be a metal such as aluminum (Al) or silver (Ag) or may be indium zinc oxide (IZO) deposited by magnetron sputtering, and has a thickness of 10 nm to 100 nm. The embodiments of the present disclosure are not limited thereto.

Between S21 and S24, the method further includes a step S23.

In S23, an adjustment layer 119 is formed.

In the above step, the adjustment layer 119 is in contact with the electron transporting layer 115. The adjustment layer 119 is of a continuous film layer structure. The adjustment layer 119 includes at least two two-dimensional semiconductor layers, and the at least two two-dimensional semiconductor layers forms a moiré superlattice structure.

For example, the adjustment layer 119 may be formed by direct deposition using a mask, or by means of mask exposure, development and etching.

S23 may be before S22 or after S22, which is not specifically limited in the present disclosure.

To sum up, in the light-emitting device 11 provided in some embodiments of the present disclosure, the plurality of adjustment patterns 118 block electrons transmitted from the first electrode 111 to the quantum dot light-emitting layer 114 or induce the electron traps to trap electrons transmitted from the first electrode 111 to the quantum dot light-emitting layer 114. In this way, in a case where it is ensured that the electrons still have a transmission channel, the plurality of adjustment patterns 118 will not block the electron transmission completely, the electron transmission channel may be narrowed and the electron transmission capacity may be reduced. In addition, the adjustment layer 119 induces electron traps to confine electrons in the superlattice structure, so that the electron transportability may be reduced, and eventually the luminous efficiency of the light-emitting device 11 may be improved.

The foregoing descriptions are merely specific implementation manners of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a first electrode;
an electron transporting layer disposed on a side of the first electrode;
a quantum dot light-emitting layer disposed on a side of the electron transporting layer away from the first electrode;
a second electrode disposed on a side of the quantum dot light-emitting layer away from the first electrode; and
a plurality of adjustment patterns, wherein orthographic projections of the plurality of adjustment patterns on a reference plane are distributed at intervals, and the reference plane is parallel to a plane in which the first electrode is located; the plurality of adjustment patterns are disposed between the first electrode and the quantum dot light-emitting layer and are each in contact with the electron transporting layer; at least a portion of an orthographic projection of the electron transporting layer on the reference plane is located in a gap between the orthographic projections of the plurality of adjustment patterns on the reference plane; and
the plurality of adjustment patterns are configured to achieve one of blocking electrons transmitted from the first electrode to the quantum dot light-emitting layer and inducing electron traps to trap the electrons transmitted from the first electrode to the quantum dot light-emitting layer.

2. The light-emitting device according to claim 1, wherein the plurality of adjustment patterns include an insulating transparent oxide material.

3. The light-emitting device according to claim 1, wherein the plurality of adjustment patterns include a hole-transporting-type transparent oxide material.

4. (canceled)

5. The light-emitting device according to claim 3, wherein a lowest unoccupied molecular orbital level of the hole-transporting-type transparent oxide material is shallower than a lowest unoccupied molecular orbital level of the electron transporting layer; and/or
the light-emitting device further comprises a hole transporting layer disposed between the quantum dot light-emitting layer and the second electrode, and a material of the plurality of adjustment patterns is the same as a material of the hole transporting layer.

6. (canceled)

7. The light-emitting device according to claim 1, wherein the plurality of adjustment patterns include at least two two-dimensional semiconductor layers, and the at least two two-dimensional semiconductor layers form a moiré superlattice structure.

8. (canceled)

9. The light-emitting device according to claim 1, wherein the plurality of adjustment patterns are arranged in a plurality of rows and a plurality of columns; and
any two adjacent rows of adjustment patterns have an equal distance therebetween, and/or any two adjacent columns of adjustment patterns have an equal distance therebetween.

10. (canceled)

11. The light-emitting device according to claim 1, wherein the plurality of adjustment patterns are disposed in the electron transporting layer;
the electron transporting layer has a first surface in contact with the first electrode, and a second surface in contact with the quantum dot light-emitting layer; in a direction perpendicular to a plane where the first electrode is located, the plurality of adjustment patterns and the first surface have a distance therebetween, and the plurality of adjustment patterns and the second surface have another distance therebetween; or
the plurality of adjustment patterns are disposed in the electron transporting layer; the electron transporting layer has the first surface in contact with the first electrode, and the second surface in contact with the quantum dot light-emitting layer; in the direction perpendicular to the plane where the first electrode is located, the plurality of adjustment patterns and the first surface have the distance therebetween, and the plurality of adjustment patterns and the second surface have the another distance therebetween; the electron transporting layer includes a first electron transporting sub-layer and a second electron transporting sub-layer, and the first electron transporting sub-layer is closer to the first electrode than the second electron transporting sub-layer; the plurality of adjustment patterns are disposed between the first electron transporting sub-layer and the second electron transporting sub-layer, and at least a portion of the second electron transporting sub-layer fills a gap between the plurality of adjustment patterns and is in contact with the first electron transporting sub-layer.

12. (canceled)

13. The light-emitting device according to claim 1, wherein the plurality of adjustment patterns are disposed between the electron transporting layer and the quantum dot light-emitting layer; or
the plurality of adjustment patterns are disposed between the electron transporting layer and the quantum dot light-emitting layer; and the quantum dot light-emitting layer is in contact with the electron transporting layer through a gap between the plurality of adjustment patterns.

14. (canceled)

15. The light-emitting device according to claim 13, wherein a number of lattice defects per unit area in a surface of the plurality of adjustment patterns in contact with the quantum dot light-emitting layer is less than a number of lattice defects per unit area in a surface of the electron transporting layer in contact with the quantum dot light-emitting layer.

16. The light-emitting device according to claim 1, wherein the plurality of adjustment patterns are disposed between the first electrode and the electron transporting layer, and the electron transporting layer is in contact with the first electrode through a gap between the plurality of adjustment patterns.

17-18. (canceled)

19. A light-emitting device, comprising:
a first electrode;
an electron transporting layer disposed on a side of the first electrode;
a quantum dot light-emitting layer disposed on a side of the electron transporting layer away from the first electrode;
a second electrode disposed on a side of the quantum dot light-emitting layer away from the first electrode; and
an adjustment layer disposed between the first electrode and the quantum dot light-emitting layer and in contact with the electron transporting layer, wherein the adjustment layer is of a continuous film layer structure, and the adjustment layer includes at least two two-dimensional semiconductor layers, and the at least two two-dimensional semiconductor layers form a moiré superlattice structure; and
the adjustment layer is configured to induce electron traps to trap electrons transmitted from the first electrode to the quantum dot light-emitting layer.

20. (canceled)

21. The light-emitting device according to claim 19, wherein an interlayer twist angle between two adjacent two-dimensional semiconductor layers is less than or equal to 10°.

22. The light-emitting device according to claim 19, wherein the electron transporting layer includes a first electron transporting sub-layer and a second electron transporting sub-layer, and in a direction perpendicular to a plane in which the first electrode is located and pointing from the first electrode to the quantum dot light-emitting layer, the first electron transporting sub-layer, the adjustment layer and the second electron transporting sub-layer are sequentially stacked; or
the adjustment layer is disposed between the electron transporting layer and the quantum dot light-emitting layer; or
the adjustment layer is disposed between the first electrode and the electron transporting layer.

23. (canceled)

24. A method for manufacturing a light-emitting device according to claim 1, the method comprising:
forming a first electrode on a substrate;
forming an electron transporting layer on a side of the first electrode away from the substrate, the electron transporting layer including an N-type inorganic semiconductor material;
forming a quantum dot light-emitting layer on a side of the electron transporting layer away from the substrate; and
forming a second electrode on a side of the quantum dot light-emitting layer away from the substrate, wherein
after forming the first electrode and before forming the quantum dot light-emitting layer, the method further comprises: forming a plurality of adjustment patterns distributed at intervals; the plurality of adjustment patterns are each in contact with the electron transporting layer; and at least a portion of an orthographic projection of the electron transporting layer on the substrate is located in a gap between orthographic projections of the plurality of adjustment patterns on the substrate.

25-28. (canceled)

29. A method for manufacturing a light-emitting device according to claim 19, the method comprising:
forming a first electrode on a substrate;
forming an electron transporting layer on a side of the first electrode away from the substrate, the electron transporting layer including an N-type inorganic semiconductor material;
forming a quantum dot light-emitting layer on a side of the electron transporting layer away from the substrate; and
forming a second electrode on a side of the quantum dot light-emitting layer away from the substrate, wherein
after forming the first electrode and before forming the quantum dot light-emitting layer, the method further comprises: forming an adjustment layer; the adjustment layer is in contact with the electron transporting layer; the adjustment layer is of a continuous film layer structure; the adjustment layer includes at least two two-dimensional semiconductor layers, and the at least two two-dimensional semiconductor layers form a moiré superlattice structure.

30. A display panel, comprising:
a backplane, the backplane including a substrate and a plurality of pixel circuits disposed on the substrate; and
a plurality of light-emitting devices disposed on the backplane, wherein the plurality of light-emitting devices are each the light-emitting device according to claim 1, a first electrode of at least one light-emitting device is closer to the backplane than a second electrode thereof, and a first electrode of a single light-emitting device is electrically connected to a pixel circuit.

31. The display panel according to claim 30, wherein a distance between two adjacent light-emitting devices is a first distance;
a distance between two adjacent adjustment patterns of a light-emitting device is a second distance; and
the second distance is less than or equal to the first distance; and/or
the light-emitting device has a light-emitting region; and an area of a plurality of adjustment patterns of the light-emitting device is less than or equal to an area of the light-emitting region.

32-33. (canceled)

34. A display apparatus, comprising
the display panel according to claim 30.

35. A display panel, comprising:
a backplane, the backplane including a substrate and a plurality of pixel circuits disposed on the substrate; and
a plurality of light-emitting devices disposed on the backplane, wherein the plurality of light-emitting devices are each the light-emitting device according to claim 19, a first electrode of at least one light-emitting device is closer to the backplane than a second electrode thereof, and a first electrode of a light-emitting device is electrically connected to a pixel circuit.

36. A display apparatus, comprising the display panel according to claim 34.
